(19) United States
(12) Patent Application Publication
(10) Pub. No.: US 2026/0284782 A1
(43) Pub. Date: Sep. 24, 2026

(54) LASER IRRADIATION APPARATUS AND LASER PROCESSING APPARATUS

(71) Applicant: SEIKO EPSON CORPORATION, Tokyo (JP)

(72) Inventors: Yoshitomo KUMAI, OKAYA-SHI (JP); Yoji KITANO, CHINO-SHI (JP)

(73) Assignee: SEIKO EPSON CORPORATION, Tokyo (JP)

(21) Appl. No.: 19/572,886

(22) Filed: Mar. 20, 2026

(30) Foreign Application Priority Data
Mar. 21, 2025 (JP) 2025-046470

(51) Int. Cl. B23K 26/03; B23K 26/064; H01S 5/11

(52) U.S. Cl. CPC B23K 26/032; B23K 26/0648; H01S 5/11

(57) ABSTRACT

A laser processing apparatus includes: a laser irradiation unit emitting laser light in which first and second light beams are converged toward a convergence point; a light receiving unit including a first light receiving element and a second light receiving element; a moving mechanism; and a controller. The first laser element and the second laser element are disposed at positions different from each other, a position at which the light receiving unit receives the laser light is different from the convergence point in an arrangement direction, a position at which the first light receiving element receives the first light beam and a position at which the second light receiving element receives the second light beam are different from each other. The controller irradiates the light receiving unit with the laser light and corrects an output of the laser light based on a light reception result of the light receiving unit.

### CROSS REFERENCE TO THE RELATED APPLICATION

The present application is based on, and claims priority from JP Application Serial Number 2025-046470, filed Mar. 21, 2025, the disclosure of which is hereby incorporated by reference herein in its entirety.

### BACKGROUND

### 1. Technical Field

The present disclosure relates to a laser irradiation apparatus and a laser processing apparatus.

### 2. Related Art

JP-A-2003-251480 discloses a laser processing apparatus that irradiates a workpiece with laser light, supplies a metal material powder to the irradiation region, melts the metal material powder with the energy of the laser light, and deposits the metal material powder thus melted on the workpiece to form a cladding layer.

JP-A-2003-251480 is an example of the related art.

In the laser processing apparatus described above, since each laser light emitted from the plurality of semiconductor lasers is focused on the irradiation region, it is difficult to individually calibrate the output of each semiconductor laser, and it is difficult to control the irradiation amount of the laser light with high accuracy.

### SUMMARY

In order to solve the problem described above, according to an aspect of the present disclosure, there is provided a laser irradiation apparatus including: a laser irradiation unit including a first laser element configured to emit a first light beam and a second laser element configured to emit a second light beam, and configured to emit laser light in which the first light beam and the second light beam are converged toward a convergence point; a light receiving unit including a first light receiving element configured to receive the first light beam and a second light receiving element configured to receive the second light beam; a moving mechanism configured to change a relative position between the laser irradiation unit and the light receiving unit; and a controller configured to control driving of the laser irradiation unit and the moving mechanism, wherein the first laser element and the second laser element are disposed at positions different from each other in a plan view of the laser irradiation unit from the convergence point, a position at which the light receiving unit receives the laser light emitted from the laser irradiation unit is different from the convergence point in an arrangement direction in which the laser irradiation unit and the light receiving unit are arranged when the laser irradiation unit and the light receiving unit face each other, in a plan view of the light receiving unit along the arrangement direction, a first position at which the first light receiving element receives the first light beam and a second position at which the second light receiving element receives the second light beam are different from each other, and the controller irradiates the light receiving unit with the laser light in a state in which the laser irradiation unit and the light receiving unit face each other, and corrects an output of the laser light based on a light reception result of the light receiving unit.

According to another aspect of the present disclosure, there is provided a laser processing apparatus including: the laser irradiation apparatus according to the aspect described above; and a stage on which a workpiece to be irradiated with the laser light by the laser irradiation unit of the laser irradiation apparatus is placed.

### BRIEF DESCRIPTION OF THE DRAWINGS

FIG. 1 is a perspective view showing a schematic configuration of a laser processing apparatus according to an embodiment.

FIG. 2 is a schematic diagram showing a configuration of a laser irradiation unit.

FIG. 3 is a diagram showing a positional relationship between the laser irradiation unit and a light receiving unit.

FIG. 4 is a diagram showing a schematic configuration of a laser irradiation apparatus according to a first modified example.

FIG. 5 is a diagram showing a schematic configuration of a laser irradiation apparatus according to a second modified example.

### DESCRIPTION OF EMBODIMENTS

An embodiment of the present disclosure will hereinafter be described with reference to the drawings.

In the following drawings, elements are drawn at different dimensional scales in some cases in order to make the elements eye-friendly.

### Embodiment

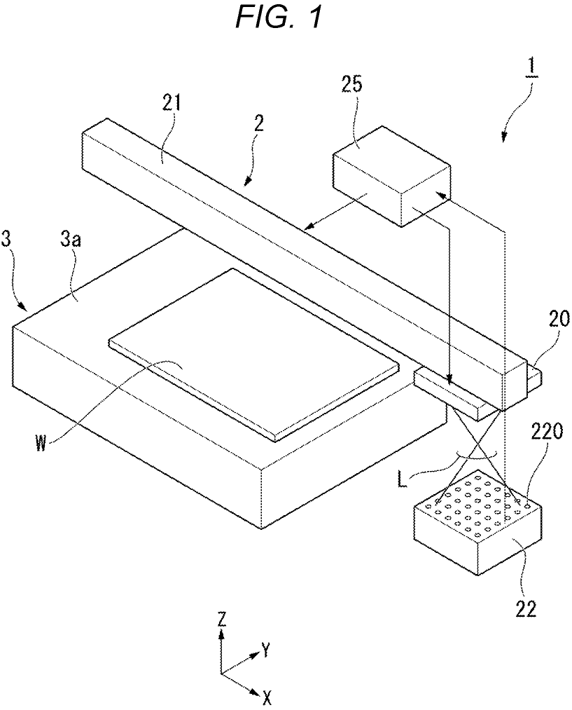

FIG. 1 is a perspective view showing a schematic configuration of a laser processing apparatus according to the present embodiment.

As illustrated in FIG. 1, the laser processing apparatus 1 of the present embodiment includes a laser irradiation apparatus 2 and a stage 3. The laser processing apparatus 1 is, for example, a metal 3D printer using selective laser melting (SLM).

The laser irradiation apparatus 2 irradiates the workpiece W with laser light L from the laser irradiation unit 20. The stage 3 has a placement surface 3a on which the workpiece W is placed.

In the following description, an X-Y-Z orthogonal coordinate system is used as necessary.

In each drawing, an X axis is an axis along a moving direction of the laser irradiation unit 20 with respect to the stage 3. The Y axis is an axis orthogonal to the X axis, and the X-Y plane is a plane parallel to a placement surface 3a of the stage 3. The Z axis is an axis orthogonal to the X axis and the Y axis, and is an axis along a vertical direction.

Further, in the description of the present embodiment, a direction along the Z axis is referred to as an "up-down direction Z", +Z is referred to as an "upper side", -Z is referred to as a "lower side", a direction along the X axis is referred to as a "left-right direction X", +X is referred to as a "right side", -X is referred to as a "left side", a direction along the Y axis is referred to as a "front-rear direction Y", +Y is referred to as a "front side", and -Y is referred to as a "rear side".

Note that the up-down direction Z, the left-right direction X, and the front-rear direction Y are merely names for describing the arrangement relationship of the components of the laser processing apparatus 1, but do not define the actual installation posture and direction in the laser processing apparatus 1.

The laser irradiation apparatus 2 of the present embodiment includes the laser irradiation unit 20, a moving mechanism 21, a light receiving unit 22, and a controller 25. The laser irradiation unit 20 emits the laser light L downward. The moving mechanism 21 moves the laser irradiation unit 20 in the left-right direction X. In the case of the present embodiment, the controller 25 controls driving of the stage 3 in addition to the moving mechanism 21.

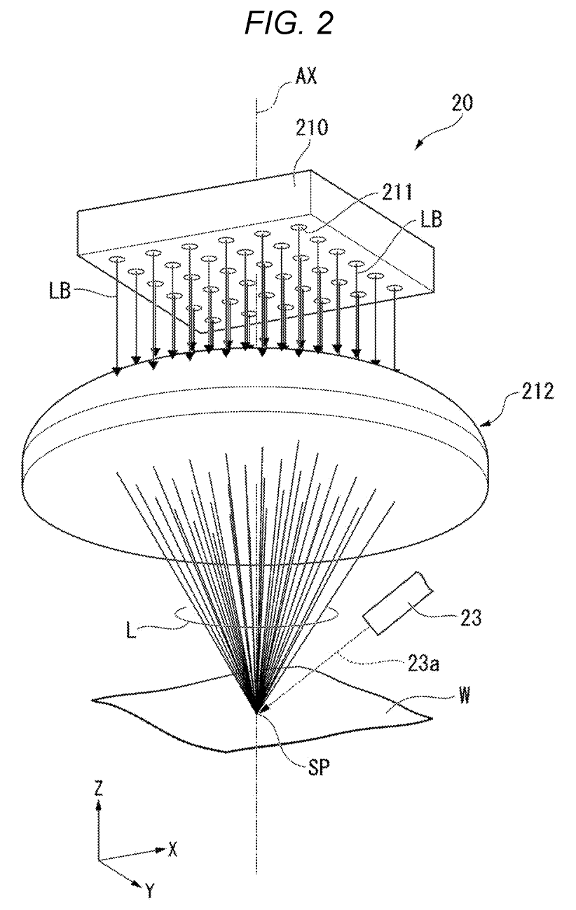

FIG. 2 is a schematic diagram illustrating a configuration of the laser irradiation unit 20.

As illustrated in FIG. 2, the laser irradiation unit 20 includes a substrate 210, a plurality of laser elements 211 supported by the substrate 210, and a condenser lens 212. The plurality of laser elements 211 is arranged in a matrix on the substrate 210. Each of the laser elements 211 emits a laser beam LB. In the example in FIG. 2, the planar shape of the laser element 211 is a circle.

The laser element 211 is, for example, a photonic crystal surface emitting laser (PCSEL) element using a photonic crystal effect. The laser beam LB emitted from the laser element 211 formed of the PCSEL element is narrow in radiation angle and high in light output.

The emission directions of the laser beams LB from the plurality of laser elements 211 are parallel to each other. The emission direction of the laser beam LB from the laser element 211 is a direction along the Z axis that is orthogonal to a virtual plane on which the plurality of laser elements 211 is arranged and coincides with the optical axis AX of the laser irradiation unit 20.

The condenser lens 212 is a convex lens, and converges the laser beams LB from the plurality of laser elements 211 toward the convergence point SP to thereby generate the high-power laser light L. The surface of the workpiece W is disposed at the convergence point SP of the laser light L.

The laser irradiation unit 20 irradiates the surface of the workpiece W with the laser light L obtained by converging the plurality of laser beams LB.

The laser irradiation unit 20 in the present embodiment further includes a material supply unit 23. The material supply unit 23 is configured with, for example, a pipe member through which the material powder can flow, and ejects the material powder 23a toward the workpiece W. As the material powder, metal powder of, for example, stainless steel, a nickel-based alloy, a cobalt-based alloy, or titanium is used. The material supplied from the material supply unit 23 to the workpiece W is not limited to powder, and may be, for example, a linear material such as a metal wire.

Based on such a configuration, the laser irradiation unit 20 can perform additive manufacturing for melting metal and forming a metal layer on the surface of the workpiece W by irradiating the surface of the workpiece W with the laser light L obtained by converging the plurality of laser beams LB and supplying the metal powder to the workpiece W.

As illustrated in FIG. 1, the moving mechanism 21 changes the relative position between the laser irradiation unit 20 and the stage 3, and the relative position between the laser irradiation unit 20 and the light receiving unit 22. In the case of the present embodiment, driving of the moving mechanism 21 is controlled by the controller 25.

For example, the moving mechanism 21 moves the laser irradiation unit 20 to create a first state in which the laser irradiation unit 20 and the light receiving unit 22 face each other. The laser processing apparatus 1 performs calibration processing of the laser irradiation apparatus 2 in the first state. The calibration processing will be described later.

Further, for example, the moving mechanism 21 moves the laser irradiation unit 20 to create a second state in which the laser irradiation unit 20 and the workpiece W face each other. In the second state, the laser processing apparatus 1 performs the processing described above by irradiating the workpiece W on the stage 3 with the laser light L from the laser irradiation unit 20 of the laser irradiation apparatus 2.

The light receiving unit 22 receives the laser light L emitted from the laser irradiation unit 20. The light receiving unit 22 includes a plurality of light receiving elements 220. The plurality of light receiving elements 220 is provided so as to correspond respectively to the plurality of laser elements 211. That is, the number of light receiving elements 220 is the same as the number of laser elements 211. Each of the light receiving elements 220 receives the laser beam LB emitted from corresponding one of the laser elements 211 to detect the intensity of the laser beam LB received. A detection value of the light receiving element 220 is transmitted to the controller 25. The light receiving element 220 includes, for example, a photodiode. The light receiving element 220 is, for example, a laser power meter or a laser energy meter. The light receiving element 220 may be an imaging element such as a CCD image sensor or a CMOS image sensor. In this case, the light receiving element 220 can detect the two-dimensional intensity distribution of the laser beam LB emitted from the laser element 211.

The stage 3 is a biaxial stage that moves the placement surface 3a on which the workpiece W is placed in biaxial directions of the left-right direction X and the front-rear direction Y. The stage 3 may adjust the position of the workpiece W with respect to the laser irradiation unit 20 by moving the placement surface 3a. Accordingly, the workpiece W can be accurately irradiated with the laser light L.

In the case of the present embodiment, driving of the stage 3 is controlled by the controller 25.

The controller 25 is configured with, for example, a computer including a processor, a main storage device, and an input/output interface for receiving input of a signal from and outputting a signal to the outside. The controller 25 exerts various functions by the processor executing programs read into the main storage device. Thus, the controller 25 controls driving of the laser irradiation apparatus 2 and the stage 3. The controller 25 may be implemented by a combination of a plurality of circuits instead of a computer.

Here, the output of the laser light L emitted by the laser irradiation apparatus 2 of the present embodiment may deviate from a design value in some cases due to, for example, deterioration of the laser element 211 over time. When the output of the laser light L changes, it becomes difficult to control the irradiation amount of the laser light L with respect to the workpiece W. Therefore, there is a possibility that the processing accuracy of the workpiece W decreases.

In contrast, in the laser processing apparatus 1 of the present embodiment, when the irradiation amount of the laser light L changes from the design value, the irradiation amount of the laser light L is corrected by performing the calibration processing in the laser irradiation apparatus 2. Accordingly, it becomes possible to improve the processing accuracy of the workpiece W by accurately controlling the irradiation amount of the laser light L with respect to the workpiece W.

The calibration processing in the laser irradiation apparatus 2 of the present embodiment will hereinafter be described.

The controller 25 controls the moving mechanism 21 to create the first state in which the laser irradiation unit 20 and the light receiving unit 22 face each other as illustrated in FIG. 1. In the first state, the laser irradiation unit 20 emits the laser light L toward the light receiving unit 22.

Specifically, the controller 25 moves the laser irradiation unit 20 with the moving mechanism 21 and causes the laser irradiation unit 20 and the light receiving unit 22 to face each other. Subsequently, the controller 25 causes the laser irradiation unit 20 to emit the laser light L. The light receiving unit 22 is irradiated with the laser light L from the laser irradiation unit 20.

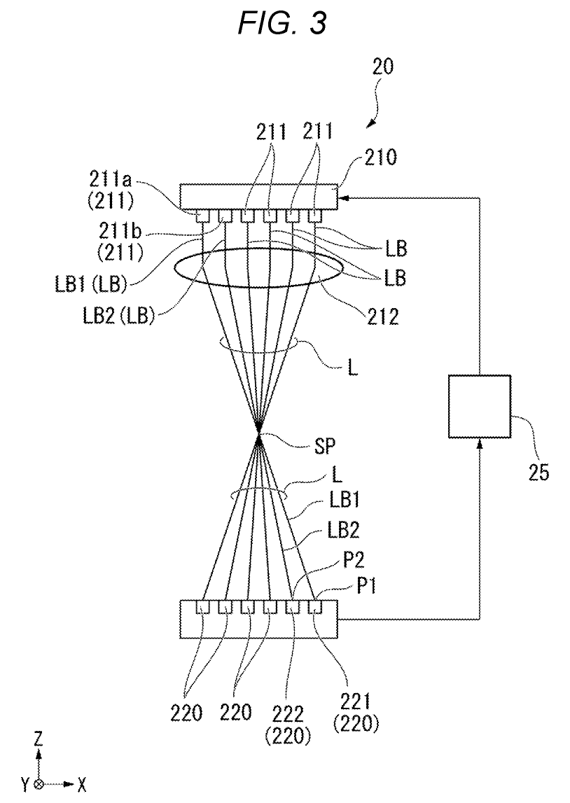

FIG. 3 is a diagram illustrating a positional relationship between the laser irradiation unit 20 and the light receiving unit 22 during the calibration processing. In FIG. 3, any two of the plurality of laser elements 211 in the laser irradiation unit 20 are referred to as a first laser element 211a and a second laser element 211b. The laser beam LB emitted from the first laser element 211a is referred to as a first light beam LB1, and the laser beam LB emitted from the second laser element 211b is referred to as a second light beam LB2. Further, out of the plurality of light receiving elements 220 in the light receiving unit 22, the light receiving element 220 that receives the first light beam LB1 from the first laser element 211a is referred to as a first light receiving element 221, and the light receiving element 220 that receives the second light beam LB2 from the second laser element 211b is referred to as a second light receiving element 222.

As shown in FIG. 3, the first light beam LB1 and the second light beam LB2 are converged together with other laser beams LB toward the convergence point SP by the condenser lens 212 to thereby generate the laser light L. In the laser light L, after the laser beams LB are converged on one point at the convergence point SP, the laser beams LB diverge as getting away from the convergence point SP. That is, the laser beams LB are spatially separated from each other as getting away from the convergence point SP. Therefore, the first light beam LB1 and the second light beam LB2 are also spatially separated from each other as getting away from the convergence point SP after crossing each other at the convergence point SP.

As illustrated in FIG. 3, the first laser element 211a and the second laser element 211b are disposed at positions different in the left-right direction X. In the laser irradiation apparatus 2 of the present embodiment, in a plan view of the laser irradiation unit 20 from the convergence point SP, the first laser element 211a and the second laser element 211b are disposed at respective positions different from each other. That is, in the plan view of the laser irradiation unit 20 from the convergence point SP, the plurality of laser elements 211 are disposed at respective positions different from each other.

In the laser irradiation apparatus 2 of the present embodiment, the position where the light receiving unit 22 receives the laser light L emitted from the laser irradiation unit 20 is different from the convergence point SP in an arrangement direction (the up-down direction Z) in which the laser irradiation unit 20 and the light receiving unit 22 are arranged when the laser irradiation unit 20 and the light receiving unit 22 face each other. Specifically, the convergence point SP is located between the laser irradiation unit 20 and the light receiving unit 22 in the arrangement direction (the up-down direction Z).

As illustrated in FIG. 3, the first light receiving element 221 and the second light receiving element 222 of the light receiving unit 22 are disposed at positions separated from the convergence point SP toward an opposite side to the laser irradiation unit 20 in the up-down direction Z. As described above, the first light beam LB1 and the second light beam LB2 are in the state of being spatially separated from each other at the arrangement position of the light receiving unit 22 separated from the convergence point SP. Therefore, the incident position of the first light beam LB1 in the first light receiving element 221 and the incident position of the second light beam LB2 in the second light receiving element 222 are shifted in the left-right direction X from each other. That is, in a plan view of the light receiving unit 22 in the arrangement direction (the up-down direction Z), a first position P1 at which the first light receiving element 221 receives the first light beam LB1 and a second position P2 at which the second light receiving element 222 receives the second light beam LB2 are different from each other.

Therefore, the first light receiving element 221 can detect the first light beam LB1 separated from the laser light L, and the second light receiving element 222 can detect the second light beam LB2 separated from the laser light L. Each of the other light receiving elements 220 can also receive the laser beam LB emitted from the corresponding one of the laser elements 211.

Since the light receiving unit 22 can receive the laser beams LB from the plurality of laser elements 211, respectively, the outputs of the respective laser elements 211 can be detected individually and at the same timing. As described above, since the light receiving unit 22 can simultaneously drive the laser elements 211 upon reception of the light, the light receiving processing can be executed in a short time compared to when sequentially driving the laser elements to perform the light reception. The light receiving unit 22 transmits the light reception result to the controller 25.

The controller 25 controls driving of the first laser element 211a and the second laser element 211b based on the light reception result of the light receiving unit 22 to thereby correct the output of the laser light L so as to have the reference value. That is, the laser irradiation unit 20 corrects the output of the laser light L with which the workpiece W is irradiated based on the light reception result of the light receiving unit 22. The reference value of the output of the laser light L is stored in a storage unit or the like disposed in the controller 25.

Here, when the controller 25 determines that the output of the first light beam LB1 is lower than the output of the second light beam LB2 based on the light reception result will be described as an example. In this case, the controller 25 corrects the output of the laser light L by controlling driving of the first laser element 211a and the second laser element 211b so as to relatively increase the output of the first laser element 211a or relatively decrease the output of the second laser element 211b.

As described above, the laser irradiation apparatus 2 according to the present embodiment includes the laser irradiation unit 20 that includes the first laser element 211a for emitting the first light beam LB1 and the second laser element 211b for emitting the second light beam LB2 and irradiates the laser light L in which the first light beam LB1 and the second light beam LB2 are converged toward the convergence point SP, the light receiving unit 22 that includes the first light receiving element 221 for receiving the first light beam LB1 and the second light receiving element 222 for receiving the second light beam LB2, the moving mechanism 21 that changes the relative position between the laser irradiation unit 20 and the light receiving unit 22, and the controller 25 that controls driving of the laser irradiation apparatus 2 and the moving mechanism 21. In a plan view of the laser irradiation unit 20 from the convergence point SP, the plurality of laser elements 211 including the first laser element 211a and the second laser element 211b is disposed at respective positions different from each other. The position where the light receiving unit 22 receives the laser light L emitted from the laser irradiation unit 20 is different from the convergence point SP in the arrangement direction in which the laser irradiation unit 20 and the light receiving unit 22 are arranged when the laser irradiation unit 20 and the light receiving unit 22 face each other. In a plan view of the light receiving unit 22 along the arrangement direction, the first position P1 at which the first light receiving element 221 receives the first light beam LB1 and the second position P2 at which the second light receiving element 222 receives the second light beam LB2 are different from each other. The controller 25 irradiates the light receiving unit 22 with the laser light L in a state where the laser irradiation unit 20 and the light receiving unit 22 face each other and corrects the output of the laser light L based on the light reception result of the light receiving unit 22.

According to the laser irradiation apparatus 2 of the present embodiment, the laser beams LB of the plurality of laser elements 211 can be individually received by the light receiving unit 22 disposed at a position different from the convergence point SP of the laser light L. Therefore, the laser irradiation unit 20 can correct the output of the laser light L by individually controlling the output of each of the laser elements 211 based on the light reception result of the light receiving unit 22. Therefore, according to the laser irradiation apparatus 2 of the present embodiment, the irradiation amount of the laser light L can be controlled with high accuracy.

The laser processing apparatus 1 of the present embodiment includes the laser irradiation apparatus 2 described above and the stage 3 on which the workpiece W to be irradiated with the laser light L by the laser irradiation unit 20 of the laser irradiation apparatus 2 is placed.

According to the laser processing apparatus 1 of the present embodiment, even when the characteristic of the laser element 211 deviates from the design value and the irradiation amount of the laser light L changes, the deviation of the irradiation amount can be corrected by the calibration processing. Accordingly, the workpiece W can be accurately processed by the processing.

The technical scope of the present disclosure is not limited to the embodiment described above, and various changes can be made thereto to the extent that the changes do not depart from the intent of the present disclosure.

For example, in the embodiment described above, when the laser light L diverging from the convergence point SP is received by the light receiving unit 22 has been described as an example, but the present disclosure is not limited thereto.

### First Modified Example

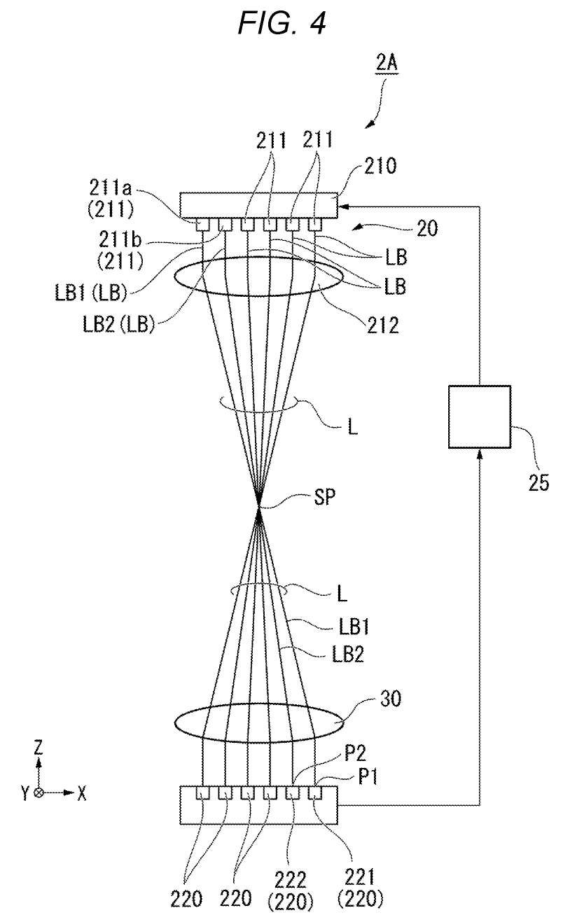

FIG. 4 is a diagram illustrating a schematic configuration of a laser irradiation apparatus according to a first modified example.

As illustrated in FIG. 4, the laser irradiation apparatus 2A of the present modified example includes the laser irradiation unit 20, the light receiving unit 22, and a collimating lens 30.

The collimating lens 30 is a convex lens, that is, a condenser lens, and is disposed between the convergence point SP and the light receiving unit 22 in the arrangement direction (the up-down direction Z) in which the laser irradiation unit 20 and the light receiving unit 22 are arranged. The convergence point SP is the focal point of the collimating lens 30. The collimating lens 30 brings the plurality of laser beams LB including the first light beam LB1 and the second light beam LB2 spreading by diverging from the convergence point SP approximate to parallel light. The collimating lens 30 is fixed to the light receiving unit 22 via a member (not illustrated).

According to the laser irradiation apparatus 2A of the present modified example, the plurality of laser beams LB constituting the laser light L can be received as parallel light by the respective light receiving elements 220 of the light receiving unit 22. Therefore, each of the light receiving elements 220 can accurately receive the laser beam LB as a parallel beam. Therefore, according to the laser irradiation apparatus 2A of the present modified example, the light receiving accuracy of the light receiving unit 22 is improved, and the irradiation amount of the laser light L can be controlled with higher accuracy.

### Second Modified Example

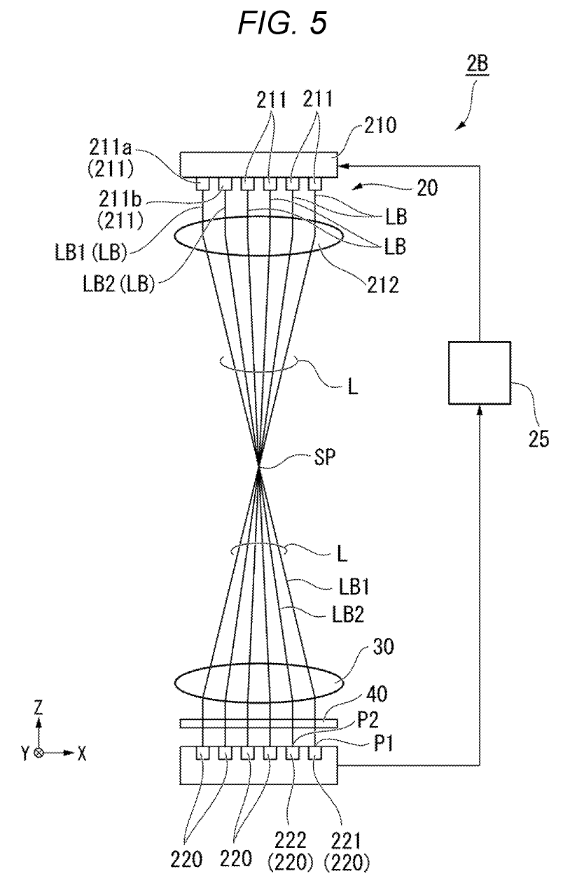

FIG. 5 is a diagram illustrating a schematic configuration of a laser irradiation apparatus according to a second modified example.

As illustrated in FIG. 5, the laser irradiation apparatus 2B of the present modified example includes the laser irradiation unit 20, the light receiving unit 22, the collimating lens 30, and a dimming element 40.

The dimming element 40 is disposed between the convergence point SP and the light receiving unit 22 in the arrangement direction (the up-down direction Z) in which the laser irradiation unit 20 and the light receiving unit 22 are arranged. The dimming element 40 is, for example, a dimming filter. In the case of the present modified example, the dimming element 40 is disposed between the collimating lens 30 and the light receiving unit 22. The dimming element 40 dims the plurality of laser beams LB including the first light beam LB1 and the second light beam LB2 having passed through the collimating lens 30.

According to the laser irradiation apparatus 2B of the present modified example, the intensity of the laser light L incident on the light receiving unit 22 can be reduced by the laser light L passing through the dimming element 40. Accordingly, it is possible to suppress damage to each of the light receiving elements 220 of the light receiving unit 22.

In addition, the specific description of the shape, number, arrangement, material, and the like of each component of the laser irradiation apparatus and the laser processing apparatus is not limited to the embodiment described above, and can be appropriately changed.

In the embodiment described above, when the convergence point SP is located between the laser irradiation unit 20 and the light receiving unit 22 in the arrangement direction (the up-down direction Z) has been described as an example. That is, although when the light receiving unit 22 is disposed at a position farther than the convergence point SP has been described as an example, the light receiving unit 22 may be disposed at a position where each laser beam before convergence can be received at a side closer to the laser irradiation unit 20, which is a near side of the convergence point SP.

Further, in the laser irradiation unit 20 of the embodiment described above, the plurality of laser elements 211 is arranged in a matrix on the substrate 210, but the plurality of laser elements 211 may be concentrically arranged on the substrate 210.

The present disclosure will be summarized below as appendices.

### Appendix 1

A laser irradiation apparatus including:

a laser irradiation unit including a first laser element configured to emit a first light beam and a second laser element configured to emit a second light beam, and configured to emit laser light in which the first light beam and the second light beam are converged toward a convergence point;

a light receiving unit including a first light receiving element configured to receive the first light beam and a second light receiving element configured to receive the second light beam;

a moving mechanism configured to change a relative position between the laser irradiation unit and the light receiving unit; and

a controller configured to control driving of the laser irradiation unit and the moving mechanism, wherein

the first laser element and the second laser element are disposed at positions different from each other in a plan view of the laser irradiation unit from the convergence point,

a position at which the light receiving unit receives the laser light emitted from the laser irradiation unit is different from the convergence point in an arrangement direction in which the laser irradiation unit and the light receiving unit are arranged when the laser irradiation unit and the light receiving unit face each other,

in a plan view of the light receiving unit along the arrangement direction, a first position at which the first light receiving element receives the first light beam and a second position at which the second light receiving element receives the second light beam are different from each other, and

the controller irradiates the light receiving unit with the laser light in a state in which the laser irradiation unit and the light receiving unit face each other, and corrects an output of the laser light based on a light reception result of the light receiving unit.

According to a laser irradiation apparatus having this configuration, by making the laser irradiation unit and the light receiving unit face each other, the first light beam and the second light beam emitted from the first laser element and the second laser element can be individually received by the light receiving unit disposed at a position different from the convergence point of the laser light. Therefore, the laser irradiation unit can simply and accurately correct the irradiation amount of the laser light by individually controlling the output of each laser element based on the light reception result of the light receiving unit.

Therefore, according to the laser irradiation apparatus having this configuration, the irradiation amount of the laser light can be controlled with high accuracy.

### Appendix 2

The laser irradiation apparatus according to Appendix 1, wherein

the laser irradiation unit further includes a condenser lens configured to generate the laser light by condensing the first light beam emitted from the first laser element and the second light beam emitted from the second laser element.

According to this configuration, by using the condenser lens, it is possible to easily and accurately generate the laser light in which the first light beam and the second light beam converge toward the convergence point.

### Appendix 3

The laser irradiation apparatus according to one of Appendices 1 and 2, further including

a collimating lens disposed between the convergence point and the light receiving unit in the arrangement direction and configured to collimate the first light beam emitted from the first laser element and the second light beam emitted from the second laser element.

According to this configuration, due to the collimating lens, the first light beam and the second light beam constituting the laser light can be made to enter the respective light receiving elements as parallel light. Therefore, each of the light receiving elements can receive each of the light beams as parallel light with high accuracy. Therefore, according to this configuration, the light receiving accuracy of the light receiving unit is improved, and the irradiation amount of the laser light can be controlled with higher accuracy.

### Appendix 4

The laser irradiation apparatus according to Appendix 3, wherein

the convergence point is a focal point of the collimating lens.

According to this configuration, the collimating lens can collimate the first light beam and the second light beam diverging from the convergence point.

### Appendix 5

The laser irradiation apparatus according to any one of Appendices 1 to 4, further including

a dimming element disposed between the convergence point and the light receiving unit in the arrangement direction and configured to dim the first light beam emitted from the first laser element and the second light beam emitted from the second laser element.

According to this configuration, the intensity of the laser light incident on the light receiving unit can be reduced by the laser light passing through the dimming element. Accordingly, it is possible to suppress damage to each of the light receiving elements of the light receiving unit.

### Appendix 6

The laser irradiation apparatus according to any one of Appendices 1 to 5, wherein

the convergence point is located between the laser irradiation unit and the light receiving unit in the arrangement direction.

According to this configuration, it is possible to realize a configuration in which the first light beam and the second light beam are received by the light receiving unit in a spatially separated state.

### Appendix 7

The laser irradiation apparatus according to any one of Appendices 1 to 6, wherein

each of the first laser element and the second laser element is a photonic crystal surface emitting laser element.

According to this configuration, the radiation angle of the laser light from the laser element can be narrowed.

### Appendix 8

A laser processing apparatus including:

the laser irradiation apparatus according to any one of Appendices 1 to 7; and

a stage on which a workpiece to be irradiated with the laser light by the laser irradiation unit of the laser irradiation apparatus is placed.

According to the laser processing apparatus having this configuration, even when the characteristic of the laser irradiation apparatus deviates from the design value and the irradiation amount of the laser light changes, the deviation of the irradiation amount can be corrected by the calibration processing. Accordingly, the workpiece can be accurately processed by the processing.

What is claimed is:

1. A laser irradiation apparatus, comprising:
a laser irradiation unit including a first laser element configured to emit a first light beam and a second laser element configured to emit a second light beam, and configured to emit laser light in which the first light beam and the second light beam are converged toward a convergence point;
a light receiving unit including a first light receiving element configured to receive the first light beam and a second light receiving element configured to receive the second light beam;
a moving mechanism configured to change a relative position between the laser irradiation unit and the light receiving unit; and
a controller configured to control driving of the laser irradiation unit and the moving mechanism, wherein
the first laser element and the second laser element are disposed at positions different from each other in a plan view of the laser irradiation unit from the convergence point,
a position at which the light receiving unit receives the laser light emitted from the laser irradiation unit is different from the convergence point in an arrangement direction in which the laser irradiation unit and the light receiving unit are arranged when the laser irradiation unit and the light receiving unit face each other,
in a plan view of the light receiving unit along the arrangement direction, a first position at which the first light receiving element receives the first light beam and a second position at which the second light receiving element receives the second light beam are different from each other, and
the controller irradiates the light receiving unit with the laser light in a state in which the laser irradiation unit and the light receiving unit face each other and corrects an output of the laser light based on a light reception result of the light receiving unit.

2. The laser irradiation apparatus according to claim 1, wherein
the laser irradiation unit further includes a condenser lens configured to generate the laser light by condensing the first light beam emitted from the first laser element and the second light beam emitted from the second laser element.

3. The laser irradiation apparatus according to claim 1, further comprising
a collimating lens disposed between the convergence point and the light receiving unit in the arrangement direction and configured to collimate the first light beam emitted from the first laser element and the second light beam emitted from the second laser element.

4. The laser irradiation apparatus according to claim 3, wherein
the convergence point is a focal point of the collimating lens.

5. The laser irradiation apparatus according to claim 1, further comprising
a dimming element disposed between the convergence point and the light receiving unit in the arrangement direction and configured to dim the first light beam emitted from the first laser element and the second light beam emitted from the second laser element.

6. The laser irradiation apparatus according to claim 1, wherein
the convergence point is located between the laser irradiation unit and the light receiving unit in the arrangement direction.

7. The laser irradiation apparatus according to claim 1, wherein
each of the first laser element and the second laser element is a photonic crystal surface emitting laser element.

8. A laser processing apparatus, comprising:
the laser irradiation apparatus according to claim 1; and
a stage on which a workpiece to be irradiated with the laser light by the laser irradiation unit of the laser irradiation apparatus is placed.
